(19) United States
(12) Patent Application Publication
(10) Pub. No.: US 2025/0370055 A1
(43) Pub. Date: Dec. 4, 2025

(54) BATTERY OPERATION

(71) Applicant: Analog Devices International Unlimited Company, Limerick (IE)

(72) Inventor: Claire Nelia LEVEUGLE, Mallow (IE)

(21) Appl. No.: 19/305,484

(22) Filed: Aug. 20, 2025

Related U.S. Application Data
(63) Continuation-in-part of application No. 18/789,088, filed on Jul. 30, 2024.
(63) Continuation-in-part of application No. 19/216,322, filed on May 22, 2025.
(60) Provisional application No. 63/520,464, filed on Aug. 18, 2023.
(60) Provisional application No. 63/650,587, filed on May 22, 2024.
(60) Provisional application No. 63/655,573, filed on Jun. 3, 2024.
(60) Provisional application No. 63/686,636, filed on Aug. 23, 2024.
(60) Provisional application No. 63/750,673, filed on Jan. 28, 2025.

(51) Int. Cl. G01R 31/389; G01R 31/36; G01R 31/367; G01R 31/374; G01R 31/382; G01R 31/392; G01R 31/396

(52) U.S. Cl. CPC G01R 31/389; G01R 31/3646; G01R 31/367; G01R 31/374; G01R 31/382; G01R 31/392; G01R 31/396

(57) ABSTRACT

The technology obtains, for each baseline cell in a baseline battery over at least one frequency, a baseline complex impedance based on EIS, and limit(s) on deviation from the baseline complex impedance. The technology measures, at least one frequency, a first measured complex impedance of cell(s) of a measurement battery. The technology determines, for each measured cell, that a difference between the first measured complex impedance and the baseline complex impedance falls outside at least one of the limit(s). The technology identifies an anomaly based on the determined difference falling outside the limit(s). The technology performs, in response to the determining: notifying an end user of a system comprising the measurement battery and a non-end user entity associated with the measurement battery of the identified anomaly; disconnecting each cell associated with the identified anomaly; deploying safety measures associated with the identified anomaly; or recording the identified anomaly.

### CROSS-REFERENCE TO RELATED APPLICATIONS

This application claims the benefit of each of U.S. Provisional Pat. App. No. 63/686,636 filed Aug. 23, 2024, and U.S. Provisional Pat. App. No. 63/750,673 filed Jan. 28, 2025. This application claims priority as a continuation-in-part (CIP) to pending U.S. patent application Ser. No. 18/789,088, filed Jul. 30, 2024; which claims the benefit of U.S. Provisional Pat. App. No. 63/520,464 filed Aug. 18, 2023, U.S. Provisional Pat. App. No. 63/650,587 filed May 22, 2024, and U.S. Provisional Pat. App. No. 63/665,573 filed Jun. 8, 2024. This application claims priority as a CIP to pending U.S. patent application Ser. No. 19/216,322, filed May 22, 2025. The disclosures of each application mentioned above are hereby incorporated herein in their entirety.

### FIELD OF THE DISCLOSURE

This disclosure relates to battery system operation, generally. More specifically, the disclosure describes technology for the use of electrochemical impedance spectroscopy (EIS) in battery operation.

### BACKGROUND

EIS can be used to characterize electrochemical systems such as single cells, batteries comprising one or more cells, and battery assemblies (including measurement and control equipment). EIS can measure the complex impedance of one or more cells over a range of frequencies—using the measurements to characterize, inter alia, energy state, storage, and dissipation properties of the cell(s), battery, or battery assembly. The data obtained through EIS can be represented in Bode plots or Nyquist plots.

The complex impedance includes a real/resistive component and an imaginary/reactive component. Such complex impedance can be measured as a universal dielectric response, whereby EIS reveals a power law relationship between the impedance and the frequency ω of an applied alternating current (AC) forcing function across a range of frequencies. Such current may be applied using a pair of force wires, and the impedance may be measured using at least one set of sense wires, often one pair of sense wires across each cell. The converse approach to measuring impedance can also be used, i.e., a voltage can be forced, and a resulting current can be observed.

### SUMMARY OF THE DISCLOSURE

In some aspects, the technology described herein relates battery operation, including: obtaining, by a computer system for each of at least one baseline cell in a baseline battery of a battery type over at least one frequency, at least one component of a complex impedance based on electrochemical impedance spectroscopy (EIS), thereby obtaining a baseline complex impedance for each baseline cell and one or more limits on deviation from the baseline complex impedance; first measuring, by a computer system using EIS over the at least one frequency, on one or more cells of a measurement battery of the battery type, each measurement battery cell corresponding to a baseline cell, the at least one component of a complex impedance, thereby obtaining a first measured complex impedance; first determining, by the computer system for each measured cell, that a difference between the first measured complex impedance and the baseline complex impedance falls outside at least one of the one or more limits; first identifying, by the computer system, an anomaly based on the determined difference falling outside at least one of the one or more limits; and performing, by the computer system and in response to the determining, one or more of: notifying one or more of an end user of a system including the measurement battery and a non-end user entity associated with the measurement battery of the identified anomaly; disconnecting each cell associated with the identified anomaly; deploying safety measures associated with the identified anomaly; and recording the identified anomaly.

In some aspects, the technology described herein relates to battery operation, including: for a baseline battery and a measurement battery each configured as a same iSjP battery type, where iS indicates i cell groups in series (S), each cell group i including j cells in parallel (P) and the baseline cell is a baseline cell group of j cells in parallel: obtaining, by one or more computer systems, a real component of complex impedance Re(Z) of a baseline cell group of a baseline cell group type at one or more frequencies for each permutation of zero or one cell of the cell group disconnected, thereby obtaining disconnected parallel cell baseline complex impedances for the baseline battery cell group; measuring, by the one or more computer systems and using EIS over the one or more frequencies, on a measurement battery cell group of the cell group type, the real component of complex impedance Re(Z), thereby obtaining a first measured complex impedance; and identifying, by the one or more computer systems, as “disconnected” a cell corresponding to the disconnected parallel cell baseline complex impedance correlating best to the measured complex impedance.

### BRIEF DESCRIPTION OF THE DRAWINGS

The present technology will now be described in more detail with reference to the accompanying drawings, which are not intended to be limiting.

FIG. 1 illustrates a typical Nyquist response, in accordance with examples of the technology disclosed herein.

FIG. 2 illustrates a battery assembly including a battery (of four cells) and EIS measurement equipment, in accordance with examples of the technology disclosed herein.

FIG. 3 illustrates methods of battery operation, in accordance with examples of the technology disclosed herein.

FIG. 4 is a flowchart for certain portions of the methods, in accordance with a first example.

FIG. 5 is a flowchart for certain portions of the methods, in accordance with a first example.

FIG. 6 is a flowchart for certain portions of the methods, in accordance with a first example.

FIG. 7 illustrates methods of battery operation, in accordance with examples of the technology disclosed herein.

FIG. 8 illustrates methods of battery operation, in accordance with examples of the technology disclosed herein.

FIG. 9 illustrates data used in an example method of battery operation, in accordance with examples of the technology disclosed herein.

FIG. 10 schematically illustrates a device that may serve as a computer/processor, in accordance with examples of the technology disclosed herein.

### DETAILED DESCRIPTION

In the following detailed description, reference is made to the accompanying drawings which form a part hereof wherein like numerals designate like parts throughout, and in which is shown by way of illustration examples that may be practiced. It is to be understood that other examples may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described example. Various additional operations may be performed and/or described operations may be omitted in additional examples.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

Various components may be referred to or illustrated herein in the singular (e.g., a “processor,” a “peripheral device,” etc.), but this is simply for ease of discussion, and any element referred to in the singular may include multiple such elements in accordance with the teachings herein.

The description uses the phrases “in an example” or “in examples,” which may each refer to one or more of the same or different examples. Furthermore, the terms “comprising,” “including,” “having,” and the like, as used with respect to examples of the present disclosure, are synonymous. As used herein, the term “circuitry” may refer to, be part of, or include an application-specific integrated circuit (ASIC), an electronic circuit, and optical circuit, a processor (shared, dedicated, or group), and/or memory (shared, dedicated, or group) that execute one or more software or firmware programs, a combinational logic circuit, and/or other suitable hardware that provide the described functionality.

Electrochemical systems include both galvanic and electrolytic electrochemical systems such as vehicle batteries, fuel cells, electrochemical capacitors, bio-electrochemical systems, electrochemical sensors, corrosion cells, photo chemical cells, thermos-galvanic cells, and electrochromic system, and can be individual cells or batteries of cells. The technology disclosed herein, while illustrated with respect to galvanic batteries of one or more cells, applies to electrochemical systems in general.

EIS can be used as a tool for generating insights into battery operation in systems such as electric vehicles (EVs), energy storage systems, and various consumer systems. For the purposes of this disclosure, a battery assembly includes: a battery, sensor(s) used to sense a parameter of the battery and/or its component(s), processor(s) in communication with memory storing instructions executable by the processor(s) to practice examples of the technology disclosed herein; and wiring connecting the sensor(s) to the processor(s). The battery can include cells or cell groups in series. Each cell group can include a plurality of cells in parallel.

Battery systems, especially those composed of multiple cells in series and parallel, may be susceptible to a range of internal defects and degradation mechanisms. These include weld defects, loss of capacity, electrolyte chemical changes, electrode movement, and general aging. Traditional monitoring methods often lack the granularity or sensitivity to detect such issues at the individual cell level, making it challenging to identify which specific cell or connection within an assembly is experiencing a problem. This may result in undiagnosed failures, reduced reliability, and unnecessary replacement of entire battery packs or modules when only a single cell may be compromised.

Battery assemblies may suffer from connection-related problems such as weld degradation, cell disconnection, or variations in mechanical components (e.g., high voltage bar thickness, sense wire routing). These issues may compromise the performance and safety of the entire battery system. Existing diagnostic approaches may not provide sufficient resolution to pinpoint the exact location or nature of such assembly defects, leading to inefficient maintenance and increased operational risk.

Thermal events, including localized overheating and thermal runaway, pose safety risks in battery systems. Conventional temperature monitoring relies on thermocouples and thermal models, which may be limited by the number of sensors that can be practically installed and the accuracy of model-based estimations. This may result in undetected or late-detected thermal events, increasing the likelihood of catastrophic failures and safety incidents.

Existing methods may require batteries to be removed from service for testing or may not provide timely or actionable information, hindering proactive maintenance and risk mitigation. Without precise identification of defective or degraded cells, maintenance actions may involve replacing entire battery packs or modules, leading to unnecessary waste and increased costs. The inability to isolate and address issues at the cell level impedes targeted interventions and reduces the overall sustainability of battery system management.

Current monitoring systems may not generate or aggregate sufficient data to enable a desired level of analysis of reliability and degradation trends across large populations of battery systems, or for a given battery over time. This limits the ability of system providers to quickly diagnose widespread issues, optimize maintenance strategies, and improve product design based on real-world performance data.

The technology disclosed herein addresses the need for improved detection and diagnosis of internal cell anomalies, connection and assembly defects, and thermal events in battery systems. It addresses the limitations of traditional monitoring methods by enabling more precise, real-time, and data-driven assessment of battery health and safety, thereby enhancing reliability, safety, and sustainability in battery system operation and maintenance.

In particular, the technology disclosed herein uses EIS to measure the complex impedance of battery cells/cell groups at one or more frequencies. By comparing these measurements to a “baseline” impedance (which can represent a healthy, expected, or simply prior, state for the cell), the technology can detect anomalies that may indicate defects, degradation, or safety issues. The process is automated and managed by one or more computer systems/processors, which can take various actions in response to detected anomalies.

For each cell (or group of cells) in a baseline battery, the technology obtains a baseline complex impedance profile using EIS. Limits are set for how much a measured impedance can deviate from this baseline before being considered abnormal. Such limits can be set by means known to those of skill in the art, including: lab measurement of a representative cell, cell group, battery, battery assembly; production line measurement of specific cell, cell, group, battery, battery assembly through its lifetime; obtaining such baseline measurements and limits from a cell, cell group, battery, battery assembly vendor; having an end-user system integrator specify frequencies, values, and limits.

The technology measures the complex impedance of cells in a battery under test (the “measurement battery”) using EIS. Each measured cell is compared to a corresponding baseline cell. If the difference between the measured and baseline impedance exceeds the predefined limits, the technology flags this as an anomaly. The technology can notify users or other entities, disconnect problematic cells, deploy safety measures, or record the anomaly, e.g., for further analysis or action.

In some aspects, the baseline can be established from the same battery at an earlier time or from a different, but similar/same type, battery. In some aspects, baseline and measurement data can be obtained through direct measurement, simulation, or data acquisition. In some aspects, the technology can perform EIS over a range of frequencies or at specific frequencies. In some aspects the technology can make adjustments for parasitic effects (unwanted influences in the measurement). In some aspects, the technology accounts for differences in conditions (such as temperature, state of charge, cell position, and system mode) between baseline and measurement. In some aspects, limits for anomaly detection can be based on cell position, historical data, or other factors.

In some aspects, the technology can identify specific types of defects based on the nature of the impedance deviation, e.g.: a shift along the real impedance axis may indicate a weld defect; a decrease in low-frequency response may indicate electrolyte degradation; a loss of area under the Nyquist plot curve may indicate reduced ampere-hour capacity.

In parallel cell group configurations, the system can identify which specific cell in a group is disconnected by comparing measured impedance to baseline permutations with one or more cells disconnected.

In some aspects, the technology can also be used to detect thermal events (potential overheating or fire risks) by analyzing impedance changes in a cell and its adjacent cells.

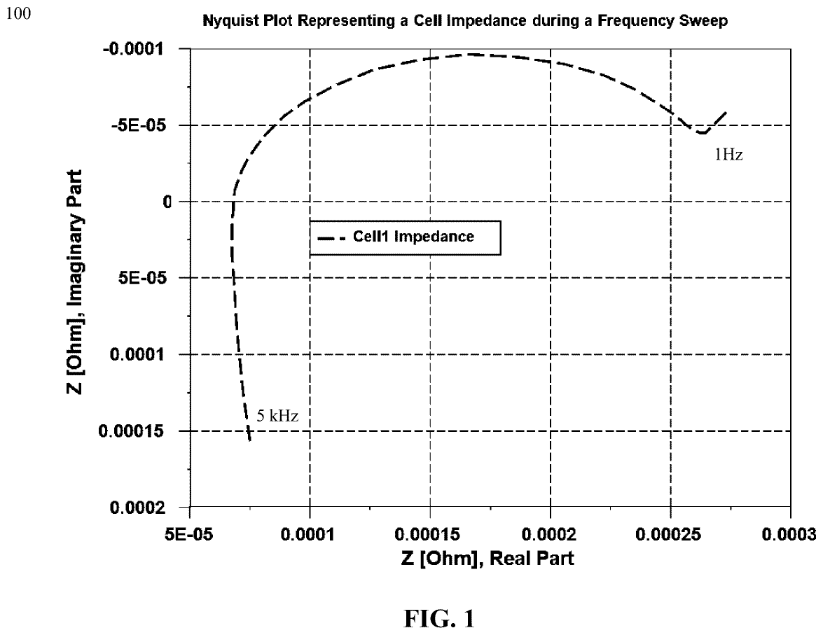

Referring to FIG. 1, a typical Nyquist response 100 for a cell tested in isolation and in low electromagnetic noise environment is illustrated, in accordance with examples of the technology disclosed herein. The cells is at a certain condition, e.g., state-of-charge (SoC), temperature, internal pressure, age, etc. In general, data points to the upper right correspond to lower frequencies of the EIS response of the cell, and points proceeding counterclockwise from the upper right correspond to higher frequencies of the EIS response to the cell. For Nyquist response 100, the frequency of the forcing function was swept from 1 Hz to 5 kHz.

Changes in the response can be associated with cell behavior in its environment. For example, a shift on response on the x-axis from a known baseline, a ΔRe(Z), can be associated with a weld defect. As another example, decrease of the area under the curve for Im(Z)<0 can be associated with a loss of capacity.

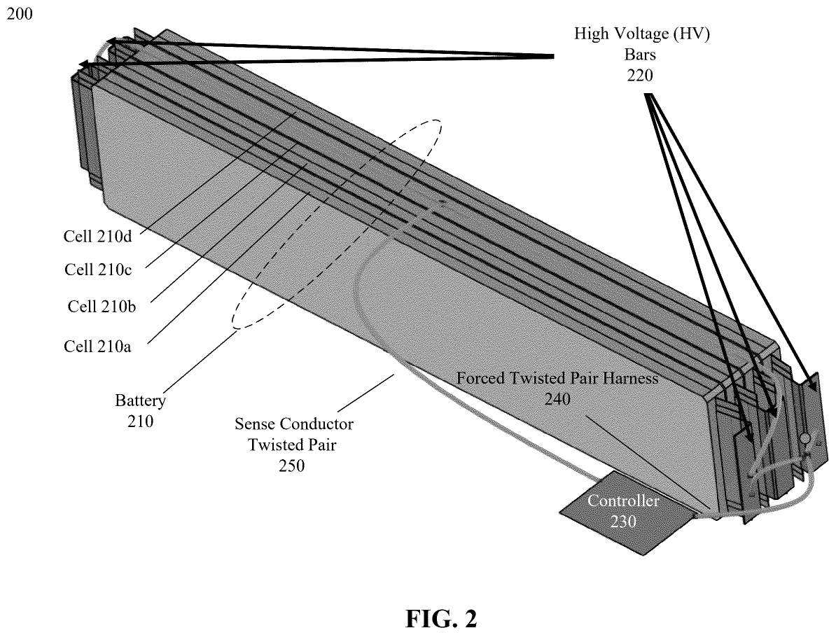

Referring to FIG. 2, and continuing to refer to prior figures for context, a battery assembly 200 including a battery 210 (of four cells 210a-210d) and EIS measurement equipment 230, 240, 250 is shown, in accordance with examples of the technology disclosed herein. The four cells 210a-210d are connected in series by high voltage (HV) bars 220 to form the battery 210. The EIS measurement equipment includes a controller 230, force conductors 240, and sense conductors 250. The conductors are shown in this example battery assembly 200 as twisted pairs, but can be single conductors with a ground return in appropriate circumstances.

The controller 230 transmits an AC forcing function over a set of force conductors 240 that are split near the right side HV bars 220 and then connected across the series-connected cells 210a to 210d. While the force conductors 240 in this example are a twisted pair, other conductors can be used. The forcing function can be any signal that contains the EIS frequencies of interest, e.g., a step pulse, a series of step pulses, a swept wave, a square wave, a series of combined individual sinusoids at different frequencies, and a stochastic broadband signal. The controller 230 independently senses the first cell 210a using a set of twisted pair of sense conductors 250 that are split to connect across the first cell 210a—only the sense conductors 250 for the first cell 210a are shown in this example. Note that twisted pair sense conductors 250 cross the first cell 210a and second cell 210b before splitting over the third cell 210c.

In general, cells in a battery can be connected in series, parallel (forming a cell group), and a combination of series and parallel. In the present disclosure, “iSjP” represents a battery composed of “i” cell groups (or one or more cells) in series “S,” with each cell group composed of “j” cells in parallel “P.”

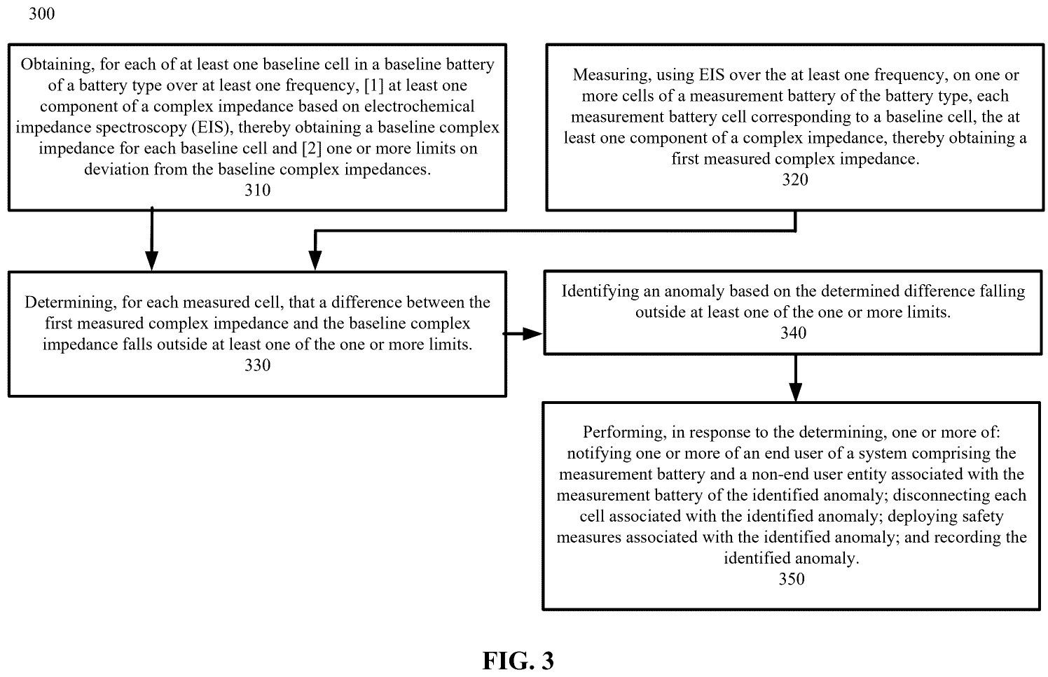

Referring to FIG. 3, and continuing to refer to prior figures for context, methods 300 of battery operation are illustrated, in accordance with examples of the technology disclosed herein.

In such methods 300, the technology obtains [1] at least one component of a complex impedance based on EIS (thereby obtaining a baseline complex impedance) for each baseline cell (or cell group) and [2] one or more limits on deviation from the baseline complex impedance for each of at least one baseline cell in a baseline battery of a battery type over at least one frequency—Block 310.

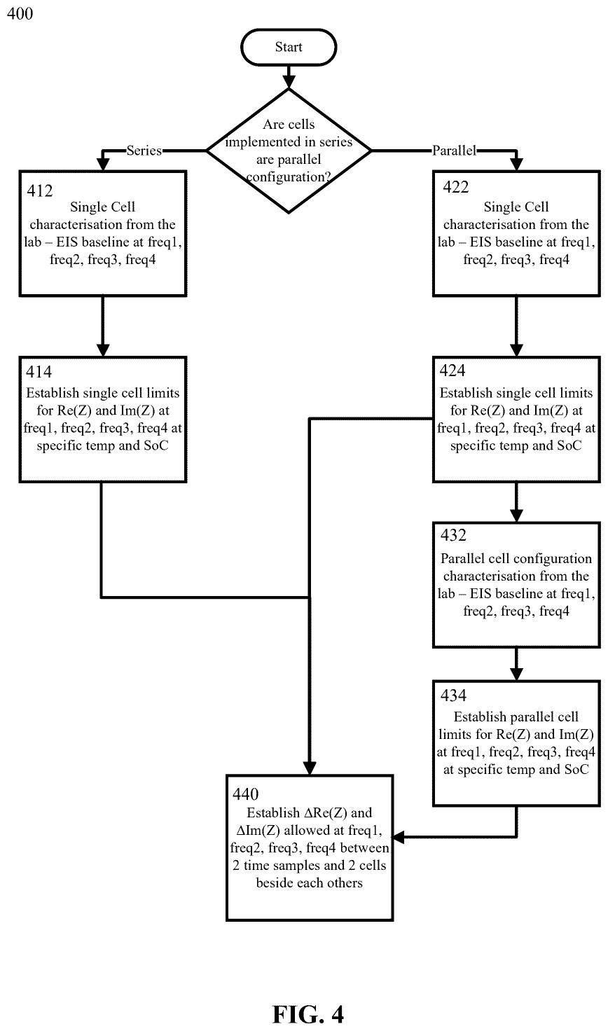

In a first example, EIS is performed on cells/cell groups of two different batteries: a 4S1P battery (such as shown in FIG. 2), and a 4S5P battery. Referring to FIG. 4, and continuing to refer to prior figures for context, a flowchart 400 for this portion of the methods 300 is illustrated, in accordance with the first example. In the continuing example, the complex impedance components Re(Z) and Im(Z) are measured at known conditions (e.g., SoC, temperature) on individual cells in pre-production for both the 4SIP and 4S5P batteries at four (4) frequencies—Block 412, Block 422. Single cell limits are established through the use of historical data on cells of batteries of the same type as the 4S1P and the 4S5P batteries using these cells—Block 414, Block 424.

In addition to obtaining single cell complex impedance measurements, 5P cell group complex impedance (where a cell group is a parallel set of cells) is measured at the same four frequencies for the 4S5P individual cells at known conditions—Block 432. As with individual cells, limits for cell group complex impedance are established through the use of historical data on cell groups of prior 4S5P batteries and 5P cell groups—Block 434. In the first example, the limits for both cells and cell groups are established as deltas from the measured values—Block 440.

In some examples, the limits can be established as a range of actual values. In some examples, baseline complex impedances can be obtained at different frequencies to allow detection of different anomaly types. In some examples, separate limits can be obtained for each of different potential anomaly types. In some examples, limits can be provided, e.g., as data, by an integrator of the end user system that includes the cells, cell groups, batteries, or battery assemblies. In some examples, limits can be obtained through simulation.

In some examples, frequencies are swept across a range-apart from, or in addition to, the use of discrete frequencies. In some examples, the limits are set by some other entity, e.g., the integrator of the system in which the battery will be used, the battery assembly manufacturer, a government regulator. In some examples, obtaining includes one or more of: obtaining as data; obtaining through simulation; and obtaining through measurement (as in the first continuing example). In each case, an EIS response at each frequency needed to identify each anomaly to be covered is obtained.

In some such examples, the complex impedance of a baseline cell/cell group is measured using equipment such as controller 230, force conductors 240, and sense conductors 250 connected to a computer (such as device 900). In some examples, the one or more frequencies include swept frequencies from <1 Hz to several kHz—though it is the useful range of characterization for the particular observation or control method that determines the frequencies of interest. In some examples, the one or more frequencies include one or more discrete frequencies across the range.

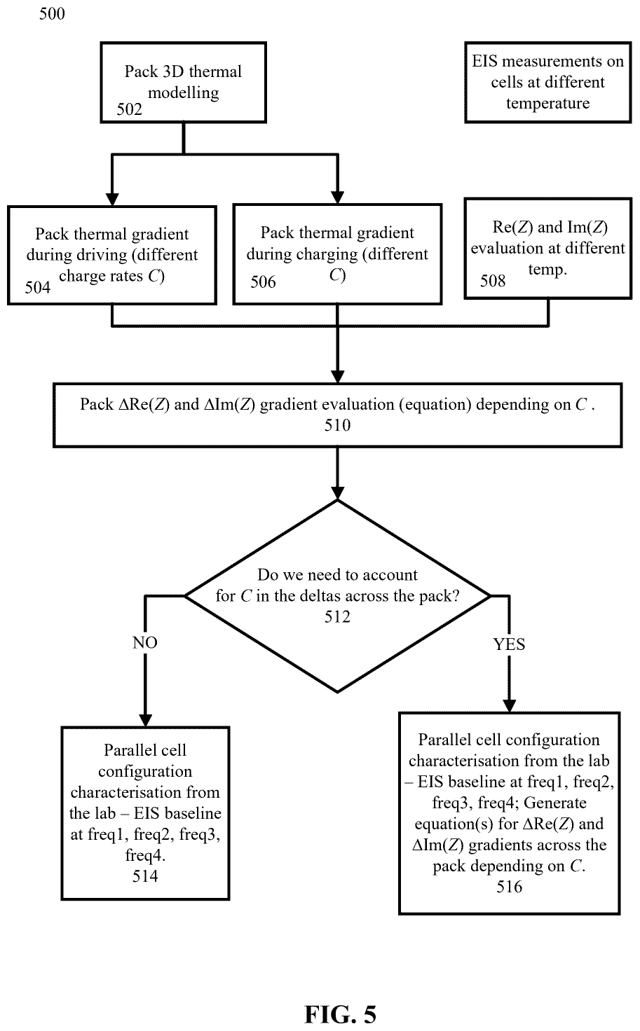

In some examples, data can be obtained to adjust the limits based, e.g., at least in part on the position of a cell in a cell group/battery, charge rate, and temperature. Referring to FIG. 5, and continuing to refer to prior figures for context, a flowchart 500 for this portion of the methods 300 is illustrated, in accordance with the first example. In the first example, a 3D thermal model 502 of a pack (a collection of cells/cell groups) is used to characterize a spatial thermal gradient during different end-system (e.g., a vehicle) modes (such as driving 504 and charging 506) at different charge rates C. The charge rate C will make the cells go to different temperatures, the thermal simulations will help infer a gradient in temperature with respect to the C rate. Some examples use this relationship and the link between the Z and the temperature. Some such examples use a first relationship with C, x, y, z and T; and a second relationship with temperature T and Z. There is one equation between C and Z for each location in the pack, and another equation or a matrix of delta(Z) as a f(C, x, y, z).

Thermal gradient characterizations are then used along with evaluation of Re(Z) and Im(Z) at different temperatures 508 to establish a complex impedance gradient dependent on cell/cell group positions and charge rate C 510. As an example, from a cell at one end of a battery to a cell at the other end, ΔRe(Z) can go from 10μΩ to 20μΩ for C>2. Depending on whether there is a need to account for charge rate C when determining thermal deltas across the pack (Block 512), the baseline complex impedance can be used unmodified (Block 514), or the baseline complex impedance can be use as modified by equation(s) for ΔRe(Z) and ΔIm(Z) gradients across the pack depending on charge rate C (516).

Referring again to FIG. 3, the technology uses EIS to measure, over the at least one frequency, on one or more cells/cell groups of a measurement battery of the battery type at known conditions, each measurement battery cell corresponding to a baseline cell, the at least one component of a complex impedance, thereby obtaining a first measured complex impedance—Block 320.

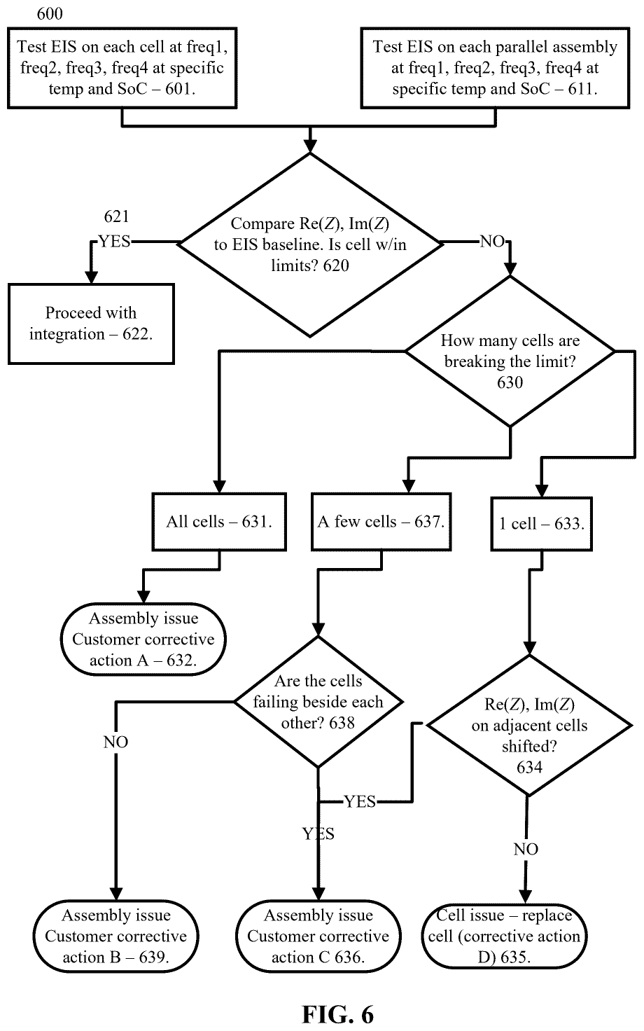

Referring to FIG. 6, and continuing to refer to prior figures for context, a flowchart 600 for this portion of the methods 300 is illustrated, in accordance with the first example. In particular, flowchart 600 is addressed to the battery assembly stage and can be practiced on cell groups, modules, packs, batteries, and battery assemblies. In this first example, the same cells and cell groups that for which baseline complex impedances were obtained under baseline conditions are now measured as part of the process for assembling the battery at the same frequency—but now under measurement conditions (e.g., temperature, SoC)—Block 601, Block 611. This measurement can be completed as described elsewhere in connection with FIG. 2 and FIG. XX.

Note that in the first example, the baseline battery and the measurement battery are the same battery—with the measurements coming after establishment of the baseline. In some examples, this is not the case. In those examples, the baseline battery is a standard applied to a plurality of measurement batteries. Also note that in the first example, complex impedance for the baseline battery cells, cell groups, and the battery itself are obtained in pre-production and production of the battery. In some other examples, the “baseline” battery can be the measurement battery at any given time before the measurement step, e.g., at a vehicle's most recent service.

At this point, one or more of the baseline complex impedance and the measured complex impedance can be compensated for differences between the baseline conditions and the measurement conditions. Such conditions can include one or more of cell state of charge (SoC), cell temperature, cell position in a battery, and mode of a system including the battery. Example technology for such compensation is described in co-pending U.S. patent application Ser. No. 19/216,322.

In addition, one or more of the baseline complex impedance and the measured complex impedance can be adjusted for parasitics, including EIS measurement system parasitics. Example technology for such adjustment is described in co-pending U.S. patent application Ser. No. 18/789,088.

Referring again to FIG. 3, the technology can determine, for each measured cell, cell group, module, pack, battery, or battery assembly, that a difference between the first measured complex impedance and the baseline complex impedance falls outside at least one of the one or more limits—Block 330. Referring again to FIG. 6, the technology compares the measured complex impedance to the corresponding baseline complex impedance (Block 620). For all complex impedances found to be within the limits (Path 621), integration of the battery assembly into the end user system (e.g., a vehicle) can proceed—Block 622.

Returning to FIG. 3, the technology can identify an anomaly based on the determined difference falling outside at least one of the one or more limits—Block 340. Referring again to the example of FIG. 6, (during battery assembly) the technology can identify an anomaly during battery assembly to a sufficient extent to choose from among various courses of action. In the example of FIG. 6., the technology determines [1] the number of cells (Block 630) and [2] the physical adjacency between cells/cell groups in series to identify the anomaly sufficient to choose from performing among four actions—{A, B, C, D}.

In some examples, identifying an anomaly includes one or more of: identifying a translation along a real impedance Re(Z) axis between the first measured complex impedance and the baseline complex impedance over time as a cell weld defect in a multicell battery; identifying a decrease in a low frequency response between the first measured complex impedance and the baseline complex impedance over time as a change in properties of electrolytes of a cell; and identifying loss of area under a EIS Nyquist plot curve for Im(Z) less than or equal to “0” between the first measured complex impedance and the baseline complex impedance over time as a reduction in an ampere-hour capacity of the cell.

Returning to FIG. 3, the technology can initiate a course of action or perform an action in response to determining that a different between the first measured complex impedance and the baseline complex impedance falls outside at least one of the one or more limits—Block 350.

Referring again to the example of FIG. 6, (during battery assembly), if all the cells/cell groups in a battery under measurement are breaking the limit(s) (Block 631) the technology can take corrective action A (Block 632)—e.g., direct that the battery be pulled from the production line for a complete inspection and rebuild. If one cell/cell group in the battery under measurement is breaking the limit(s) (Block 633), then the technology can check/re-check the complex impedance of adjacent cells (Block 634). If the complex impedance of no cells adjacent to the out-of-limit cell have shifted from baseline, then the technology can take corrective action D (Block 635)—e.g., replace just the single out-of-limit cell. Note that the threshold shift in adjacent cell(s) can be a value different than the limits on change in complex impedance of a cell.

If cells/cell groups adjacent to the out-of-limit cell/cell groups have shifted, then the technology can take corrective action C (Block 636)—e.g., inspect and replace (if necessary) each cell. If a few cells/cell groups in a battery under measurement are breaking the limit(s) (Block 637), then the technology can check for adjacency (or some other common property) of the cells (Block 638). If the cells/cell groups out-of-limit are adjacent, then the technology can take corrective action C (Block 636)—e.g., inspect and replace (if necessary) each cell. If the cells/cell groups out-of-limit are not adjacent, then the technology can take corrective action B—e.g., replace each out-of-limit cell and inspect subsystems of the common property (Block 639).

The approach described in connection with FIG. 3 and FIG. 6 can be used during production and assembly of an end-user system, e.g., a vehicle. The approach can also be used during various modes of the operational life of the end user system, e.g., vehicle-key off, vehicle-driving, and vehicle-charging. In such operational life usages, a rate of measuring (optionally after a break-in period across one or more modes) can be used. Event-driven measuring can be used instead of, or in addition to, periodic measuring. Data collected on complex impedance, recommended (and taken) actions, and conditions can be recorded (or relayed through telemetry), e.g., to facilitate assessments over the life of a cell, cell group, battery, battery assembly, end use system.

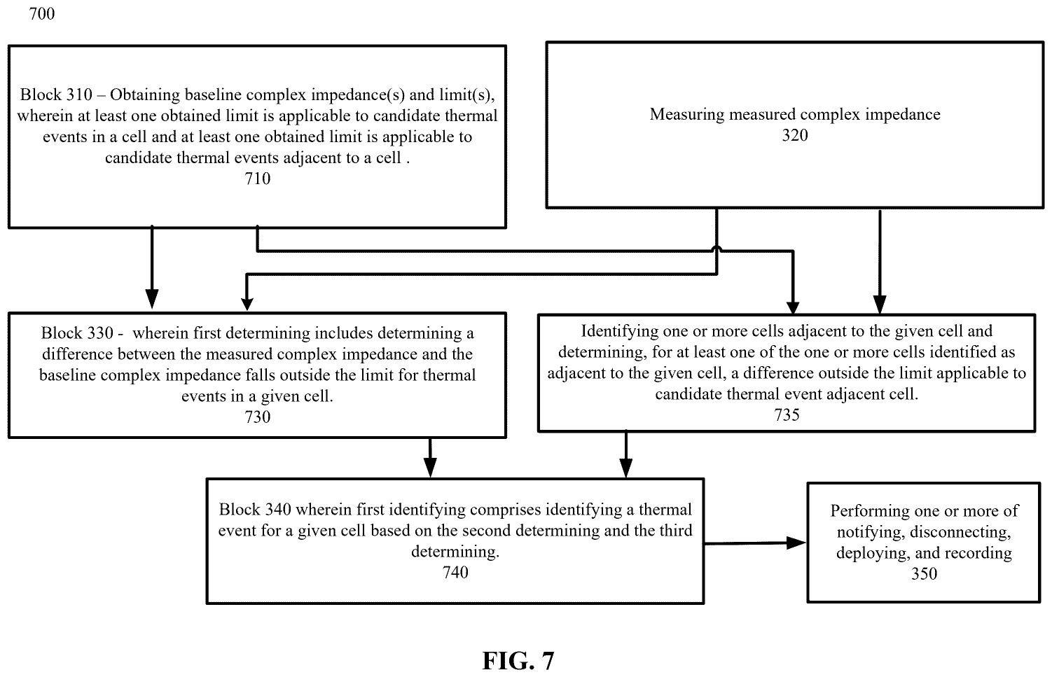

Referring to FIG. 7, and continuing to refer to prior figures for context, methods 700 for detecting thermal events (e.g., potential overheating or fire risks) in a battery are shown, in accordance with examples of the technology disclosed herein. Such methods are similar to the methods 300 described in connection with FIG. 3.

In such methods 700, the obtaining of a baseline complex impedance of Block 310 comprises obtaining at least one limit applicable to candidate thermal events in a cell and at least one limit applicable to candidate thermal events adjacent to a cell—Block 710.

In some examples, the limit applicable to thermal events in a cell and adjacent cells are the same limit. In a second example of a 6S1P battery, the limit applicable to candidate thermal events in a given cell is a ≅10μΩ change in the Re(Z) from the baseline complex impedance to the measured complex impedance. The limit applicable to candidate thermal events in adjacent cells is a ≥5μΩ change in the Re(Z) from the baseline complex impedance to the measured complex impedance.

In such methods 700, the first determining of Block 330 includes second determining a difference between the measured complex impedance and the baseline complex impedance falls outside the limit for thermal events in a given cell—Block 730. In the second continuing example, the differences over time shown in TABLE 1 were found for the 6S1P battery with t₀ being some time after the battery was installed in an end use system. In this second example, the difference between the measured complex impedance and the baseline complex impedance falls outside the limit for thermal events in a Cell #4 (the “given cell”) at time t₂—the underlined 10μΩ.

TABLE 1

| CELL | Re(Z)(t₁ − t₀) | Re(Z)(t₂ − t₀) | Re(Z)(t₃ − t₀) |
|---|---|---|---|
| 1 | 0 Ω | 0 Ω | 0 Ω |
| 2 | 0 Ω | 1 Ω | 2 Ω |
| 3 | 1 Ω | 3 Ω | 6 Ω |
| 4 | 2 Ω | 10 Ω | 15 Ω |
| 5 | 0 Ω | 2 Ω | 5 Ω |
| 6 | 0 Ω | 1 Ω | 2 Ω |

In addition to the steps of methods 300, methods 700 include identifying one or more cells adjacent to the given cell, and third determining, for at least one of the one or more cells identified as adjacent to the given cell, a difference outside the limit applicable to candidate thermal event adjacent cells—Block 735. In the second example, Cell #3 and Cell #5 are identified as adjacent. But at time t₂ neither Cell #3 nor Cell #5 have change in the Re(Z) from the baseline complex impedance to the measured complex impedance ≥5μΩ (the limit on thermal event adjacent cells). However, at t₃ both Cell #3 and Cell #5 have a change in the Re(Z) from the baseline complex impedance to the measured complex impedance ≥5μΩ (the limit on thermal event adjacent cells).

In methods 700, the identification of an anomaly per Block 340 includes identifying a thermal event for a given cell based on the second determining and the third determining—Block 740. In the second example, at t₃ both Cell #3 and Cell #5 have a change in the Re(Z) from the baseline complex impedance to the measured complex impedance ≥5μΩ (the limit on thermal event adjacent cells). So at t₃ the technology identifies a thermal event anomaly at Cell #4 in the 6S1P battery.

As with methods 300, methods 700 perform, in response to each determining, one or more of: notifying one or more of an end user of a system comprising the measurement battery and a non-end user entity associated with the measurement battery of the identified thermal event; disconnecting each cell associated with the identified thermal event; deploying safety measures associated with the identified thermal event; and recording the identified thermal event—Block 350.

As with the first example, the second example uses a change from the baseline complex impedance to the measured complex impedance as an indication of an anomaly. In some examples, values or ranges of values are used, e.g., instead of ΔRe(Z) being ≥5μΩ, the limit may be expressed as Re(Z) being ≥12μΩ.

This technology allows EIS adopters to detect, for example: internal cell initial defect or degradation; electrodes getting closer to each other; electrolyte chemical change; ageing in general; cell assembly initial defect, variation or degradation such as cell disconnection (e.g., in parallel cell assemblies), weld degradation (e.g., corrosion), and variation in the pack or rack mechanical entities (e.g., high voltage bar thickness, sense wires routing). By monitoring each cell impedance on a regular basis and harvesting the data, e.g., in the cloud, reliability and degradation issues can be debugged (e.g., by the end user system provider) as a large amount of data will be available for analysis. The technology disclosed herein can help identity defects at cell level, allowing users to limit unnecessary waste of cells, as instead of retiring a full pack or rack, or even a parallel cell configuration, the user will be able to identify the one cell with a degradation and change only this one cell in the assembly (green credit).

In some examples, where a cell group i is arranged as a plurality of j cells in parallel with one or more cell groups in series, i.e., an iSjP battery, the technology disclosed herein can be used to locate a disconnection among the parallel cells of a cell group based on the magnitude of the change in Re(Z) from a baseline complex impedance with zero disconnections. In some examples, e.g., where getting Re(Z) at IM(Z₀)=0 can be impractical, instead of taking Re(Z) at IM(Z₀)=0, the technology looks at one or a set of frequencies to eval Re(Z). If the shift in Re(Z) at all those one or more frequencies is the same, then the technology identifies a weld issue.

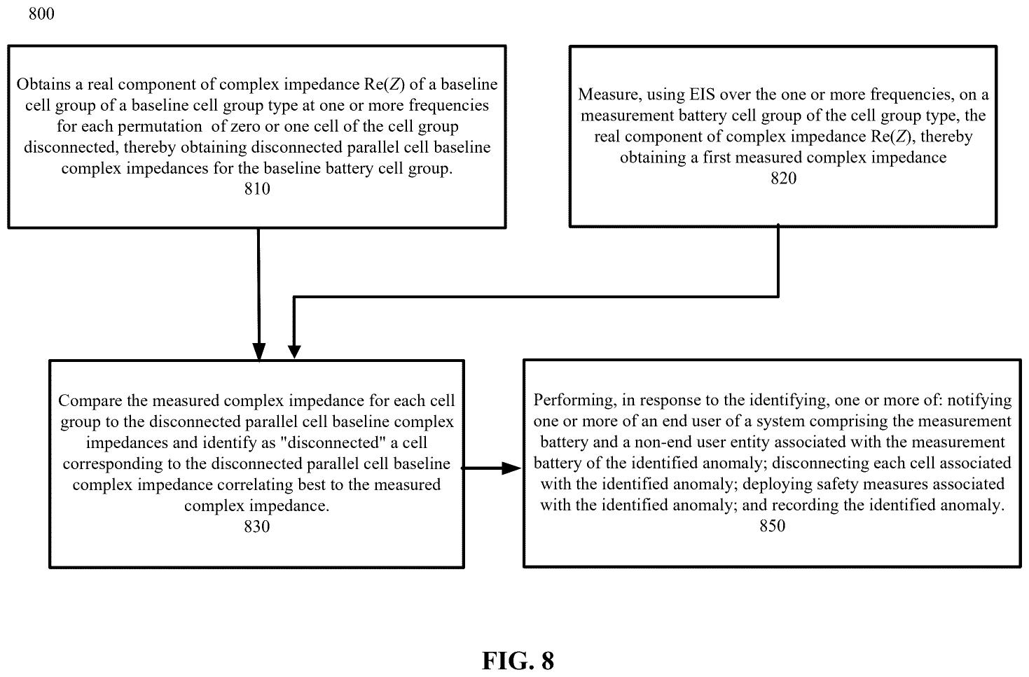

Referring to FIG. 8, and continuing to refer to prior figures for context, a method 800 is shown, in accordance with examples of the technology disclosed herein. In such methods, the technology obtains a real component of complex impedance Re(Z) of a baseline cell group of a baseline cell group type at one or more frequencies for each permutation of zero or one cell of the cell group disconnected, thereby obtaining disconnected parallel cell baseline complex impedances for the baseline battery cell group—Block 810. In a second continuing example, the disconnected parallel cell baseline complex impedance for the various permutations of one parallel cell disconnected can be obtained by a measurement using EIS. In some examples, the disconnected cell baseline complex impedance can be obtained as data from one or more of a vendor, analysis, simulation, etc. In some examples, impedances for each permutation of two, three, or N of the parallel cells in the cell group disconnected can be obtained. In some examples, a set of limits, ranges, deltas can be obtained for the impedance/change in impedance corresponding to one or more of the permutations.

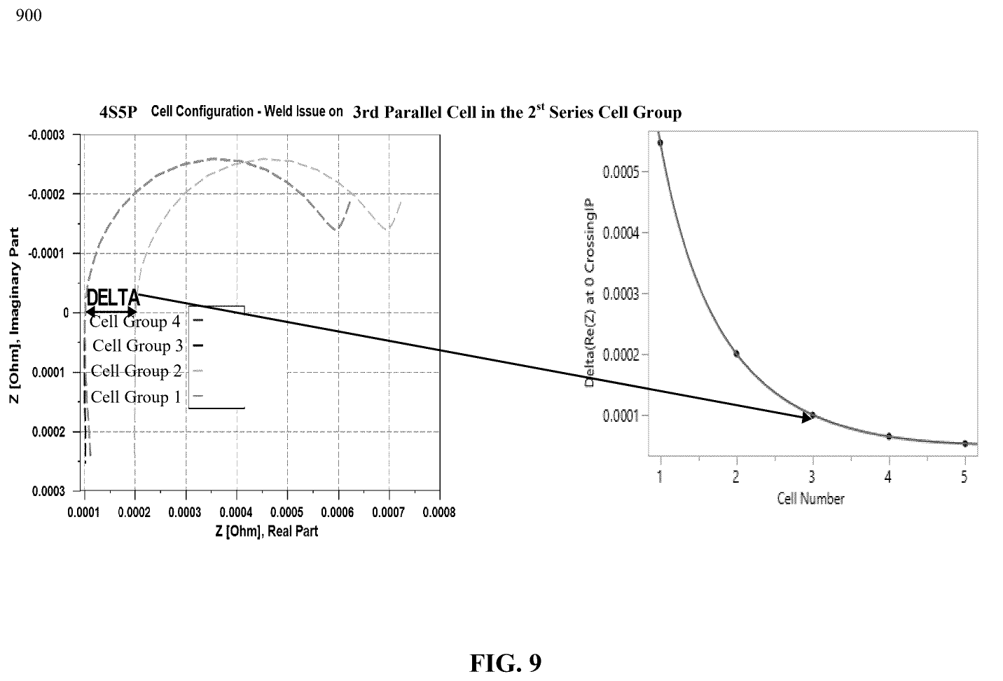

Referring to FIG. 9, and continuing to refer to prior figures for context, data 900 for the series cell group #2 in a 4S5P battery is shown, in accordance with the second continuing example. In this example, the Nyquist EIS response curve for cell groups #1, #3, and #4 overlap at the baseline complex impedance for no parallel cell disconnections with an Re(Z) value of about 0.0001Ω at the Im(Z)=0 crossing of the Nyquist plot. This Nyquist response curve also applies to cell group #2 with no parallel cell disconnections. Cell Group #2, with only parallel cell #3 disconnected, shows an Re(Z) value of about 0.0002Ω at the Im(Z)=0 crossing—a delta of about 0.0001Ω on the Re(Z) axis. Disconnection of different parallel cells within the same cell group will show different deltas—e.g., an ΔRe(Z) value of about 0.00058Ω at the Im(Z)=0 crossing for cell #1 disconnected. Either the values, or these differences (e.g., expressed as deltas, values, percentages, ranges) can serve as a baseline complex impedance for the various permutations.

FIG. 9 also shows the delta Re(Z) at the Im(Z)=0 crossing of the Nyquist plot for cell #1, cell #2, cell #4, and cell #5 of any one cell group being disconnected individually. Together, the points of this curve form the disconnected parallel cell baseline complex impedances for cell groups of this cell group type. Here the relationship between cell # and delta Re(Z) at the Im(Z)=0 can be approximated by the following relationship.

$$Delta \begin{matrix}( Re ( Z ) at Im ( Z ) = 0 ) = a - b * log ( cell ♯ ) - c * {log ( cell ♯ )}^{2} - d * {log ( cell ♯ )}^{3} & ( 1 )\end{matrix}$$

The parameters of this relationship can change depending on where the sense wires are connected on the parallel cell group.

Returning to FIG. 8, the technology can measure, by the one or more computer systems and using EIS over the one or more frequencies, on a measurement battery cell group of the cell group type, the real component of complex impedance Re(Z), thereby obtaining a first measured complex impedance—Block 820. In the second continuing example, EIS is used on each cell group of a measurement battery of battery type 4S5P. EIS of the cell group #2 returns a measured complex impedance value for Re(Z) at the Im(Z)=0 of about 0.00022Ω—corresponding to a delta from the no disconnection baseline of about 0.00012Ω. EIS of the other cell groups returns a measured complex impedance value for Re(Z) at the Im(Z)=0 of about 0.00001Ω—corresponding to a delta from the no disconnection baseline of about 0 Ω.

The technology can compare the measured complex impedance for each cell group to the disconnected parallel cell baseline complex impedances and identify as “disconnected” a cell corresponding to the disconnected parallel cell baseline complex impedance correlating best to the measured complex impedance—Block 830. In the second continuing example of FIG. 9, the measured complex impedance of each of cell group #1, cell group #3, and cell group #4 correlates best with the disconnected parallel cell baseline complex impedance for no disconnections. However, the measured complex impedance for cell group #2 correlates best with the disconnected parallel cell baseline complex impedance for a disconnected cell #3 in cell group #2. Consequently, the technology identifies cell #3 in cell group #2 as disconnected.

In the second continuing example, “correlating best” means “nearest.” In some examples, “correlating best” means more within a range around the nominal disconnected parallel cell baseline complex impedance corresponding to the cell being disconnected. For example, in FIG. 9 a range of ΔRe(Z) between 0.00014Ω and less than 0.00040Ω can correspond to parallel cell #2 being disconnected, while a range of ΔRe(Z) between and 0.00005Ω and less than 0.00014Ω can correspond to cell #3 being disconnected. A measured complex impedance of the cell group that results in a ΔRe(Z) of 0.00014Ω is nearest to the value for cell #3 being disconnected, but with the established ranges 0.00014Ω correlates best with the value for cell #2 being disconnected.

In some examples, the technology can perform, in response to the identifying, one or more of: notifying one or more of an end user of a system comprising the measurement battery and a non-end user entity associated with the measurement battery of the identified disconnection; disconnecting the cell group associated with the identified cell disconnection; deploying safety measures associated with the identified disconnection; and recording the identified disconnection—Block 850.

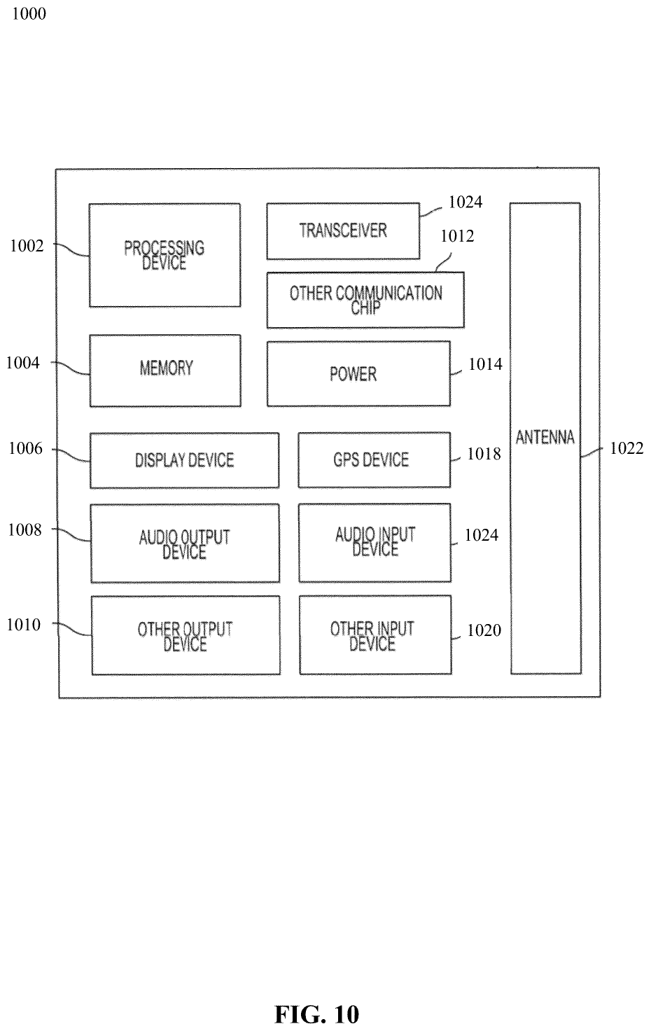

Examples of the present disclosure may be implemented into a system using any suitable hardware and/or software to configure as desired. Referring to FIG. 10, and continuing to refer to prior figures for context, FIG. 10 schematically illustrates a device 1000 that may serve as a computer/processor, in accordance with various examples. A number of components are illustrated in FIG. 10 as included in the device 1000, but any one or more of these components may be omitted or duplicated, as suitable for the application.

Additionally, in various examples, the device 1000 may not include one or more of the components illustrated in FIG. 10, but the device 1000 may include interface circuitry for coupling to the one or more components. For example, the device 1000 may not include a display device 1006, but may include display device interface circuitry (e.g., a connector and driver circuitry) to which a display device 1006 may be coupled. In another set of examples, the device 1000 may not include an audio input device 1024 or an audio output device 1008, but may include audio input or output device interface circuitry (e.g., connectors and supporting circuitry) to which an audio input device 1024 or audio output device 1008 may be coupled.

The device 1000 may include a transceiver 1024, in accordance with any of the examples disclosed herein, for managing communication along the bus when the device 1000 is coupled to the bus. The device 1000 may include a processing device 1002 (e.g., one or more processing devices), which may be included in the node transceiver or separate from the node transceiver. As used herein, the term “processing device” may refer to any device or portion of a device that processes electronic data from registers and/or memory to transform that electronic data into other electronic data that may be stored in registers and/or memory. The processing device 1002 may include one or more DSPs, ASICs, central processing units (CPUs), graphics processing units (GPUs), crypto-processors, or any other suitable processing devices. The device 1000 may include a memory 1004, which may itself include one or more memory devices such as volatile memory (e.g., dynamic random-access memory (DRAM)), non-volatile memory (e.g., read-only memory (ROM)), flash memory, solid state memory, and/or a hard drive.

In some examples, the memory 1004 may be employed to store a working copy and a permanent copy of programming instructions to cause the device 1000 to perform any suitable ones of the techniques disclosed herein. In some examples, machine-accessible media (including non-transitory computer-readable storage media), methods, systems, and devices for performing the above-described techniques are illustrative examples disclosed herein for communication over a two-wire bus. For example, a computer-readable media (e.g., the memory 1004) may have stored thereon instructions that, when executed by one or more of the processing devices included in the processing device 1002, cause the device 1000 to perform any of the techniques disclosed herein.

In some examples, the device 1000 may include another communication chip 1012 (e.g., one or more other communication chips). For example, the communication chip 1012 may be configured for managing wireless communications for the transfer of data to and from the device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some examples they might not.

The communication chip 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The one or more communication chips 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The one or more communication chips 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The one or more communication chips 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1012 may operate in accordance with other wireless protocols in other examples. The device 1000 may include an antenna 1022 to facilitate wireless communications and/or to receive other wireless communications (such as AM or FM radio transmissions).

In some examples, the communication chip 1012 may manage wired communications using a protocol other than the protocol for the bus described herein. Wired communications may include electrical, optical, or any other suitable communication protocols. Examples of wired communication protocols that may be enabled by the communication chip 1012 include Ethernet, controller area network (CAN), I2C, media-oriented systems transport (MOST), or any other suitable wired communication protocol.

As noted above, the communication chip 1012 may include multiple communication chips. For instance, a first communication chip 1012 may be dedicated to shorter-range wireless communications such as Wi-Fi or Bluetooth, and a second communication chip 1012 may be dedicated to longer-range wireless communications such as global positioning system (GPS), EDGE, GPRS, CDMA, WiMAX, LTE, EV-DO, or others. In some examples, a first communication chip 1012 may be dedicated to wireless communications, and a second communication chip 1012 may be dedicated to wired communications.

The device 1000 may include battery/power circuitry 1014. The battery/power circuitry 1014 may include one or more energy storage devices (e.g., batteries or capacitors) and/or circuitry for coupling components of the device 1000 to an energy source separate from the device 1000 (e.g., AC line power, voltage provided by a car battery, etc.).

The device 1000 may include a display device 1006 (or corresponding interface circuitry, as discussed above). The display device 1006 may include any visual indicators, such as a heads-up display, a computer monitor, a projector, a touchscreen display, a liquid crystal display (LCD), a light-emitting diode display, or a flat panel display, for example.

The device 1000 may include an audio output device 1008 (or corresponding interface circuitry, as discussed above). The audio output device 1008 may include any device that generates an audible indicator, such as speakers, headsets, or earbuds, for example.

The device 1000 may include an audio input device 1024 (or corresponding interface circuitry, as discussed above). The audio input device 1024 may include any device that generates a signal representative of a sound, such as microphones, microphone arrays, or digital instruments (e.g., instruments having a musical instrument digital interface (MIDI) output).

The device 1000 may include a GPS device 1018 (or corresponding interface circuitry, as discussed above). The GPS device 1018 may be in communication with a satellite-based system and may receive a location of the device 1000, as known in the art.

The device 1000 may include another output device 1010 (or corresponding interface circuitry, as discussed above). Examples of the other output device 1010 may include an audio codec, a video codec, a printer, a wired or wireless transmitter for providing information to other devices, or an additional storage device. Additionally, any suitable ones of the peripheral devices may be included in the other output device 1010.

The device 1000 may include another input device 1020 (or corresponding interface circuitry, as discussed above). Examples of the other input device 1020 may include an accelerometer, a gyroscope, an image capture device, a keyboard, a cursor control device such as a mouse, a stylus, a touchpad, a bar code reader, a Quick Response (QR) code reader, or a radio frequency identification (RFID) reader. Additionally, any suitable ones of the sensors or peripheral devices may be included in the other input device 1020.

Any suitable ones of the display, input, output, communication, or memory devices described above with reference to the device 1000 may serve as the peripheral device in system of the technology disclosed herein. Alternatively or additionally, suitable ones of the display, input, output, communication, or memory devices described above with reference to the device 1000 may be included in a host or a node (e.g., a main node or a sub node).

Although various ones of the examples discussed above describe the system of the technology disclosed herein in a vehicle setting, this is simply illustrative, and the system of the technology disclosed herein may be implemented in any desired setting. For example, in some examples, a “suitcase” implementation of the system of the technology disclosed herein may include a portable housing that includes the desired components of the system of the technology disclosed herein; such an implementation may be particularly suitable for portable applications, such as portable karaoke or entertainment systems.

Having thus described several aspects and examples of the technology of this application, it is to be appreciated that various alterations, modifications, and improvements will readily occur to those of ordinary skill in the art. Such alterations, modifications, and improvements are intended to be within the spirit and scope of the technology described in the application. For example, those of ordinary skill in the art will readily envision a variety of other means and/or structures for performing the function and/or obtaining the results and/or one or more of the advantages described herein, and each of such variations and/or modifications is deemed to be within the scope of the examples described herein.

Those skilled in the art will recognize or be able to ascertain using no more than routine experimentation, many equivalents to the specific examples described herein. It is, therefore, to be understood that the foregoing examples are presented by way of example only and that, within the scope of the appended claims and equivalents thereto, inventive examples may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

The foregoing outlines features of one or more examples of the subject matter disclosed herein. These examples are provided to enable a person having ordinary skill in the art (PHOSITA) to better understand various aspects of the present disclosure. Certain well-understood terms, as well as underlying technologies and/or standards may be referenced without being described in detail. It is anticipated that the PHOSITA will possess or have access to background knowledge or information in those technologies and standards sufficient to practice the teachings of the present disclosure.

The PHOSITA will appreciate that they may readily use the present disclosure as a basis for designing or modifying other processes, structures, or variations for carrying out the same purposes and/or achieving the same advantages of the examples introduced herein. The PHOSITA will also recognize that such equivalent constructions do not depart from the spirit and scope of the present disclosure, and that they may make various changes, substitutions, and alterations herein without departing from the spirit and scope of the present disclosure.

The above-described examples may be implemented in any of numerous ways. One or more aspects and examples of the present application involving the performance of processes or methods may utilize program instructions executable by a device (e.g., a computer, a processor, or other device) to perform, or control performance of, the processes or methods.

In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other tangible computer storage medium) encoded with one or more programs that, when executed on one or more computers or other processors, perform methods that implement one or more of the various examples described above.

The computer readable medium or media may be transportable, such that the program or programs stored thereon may be loaded onto one or more different computers or other processors to implement various ones of the aspects described above. In some examples, computer readable media may be non-transitory media.

Note that the activities discussed above with reference to the FIGURES which are applicable to any integrated circuit that involves signal processing (for example, gesture signal processing, video signal processing, audio signal processing, analog-to-digital conversion, digital-to-analog conversion), particularly those that can execute specialized software programs or algorithms, some of which may be associated with processing digitized real-time data.

In some cases, the teachings of the present disclosure may be encoded into one or more tangible, non-transitory computer-readable mediums having stored thereon executable instructions that, when executed, instruct a programmable device (such as a processor or DSP) to perform the methods or functions disclosed herein. In cases where the teachings herein are embodied at least partly in a hardware device (such as an ASIC, IP block, or SoC), a non-transitory medium could include a hardware device hardware-programmed with logic to perform the methods or functions disclosed herein. The teachings could also be practiced in the form of Register Transfer Level (RTL) or other hardware description language such as VHDL or Verilog, which can be used to program a fabrication process to produce the hardware elements disclosed.

In example implementations, at least some portions of the processing activities outlined herein may also be implemented in software. In some examples, one or more of these features may be implemented in hardware provided external to the elements of the disclosed figures, or consolidated in any appropriate manner to achieve the intended functionality. The various components may include software (or reciprocating software) that can coordinate in order to achieve the operations as outlined herein. In still other examples, these elements may include any suitable algorithms, hardware, software, components, modules, interfaces, or objects that facilitate the operations thereof.

Any suitably configured processor component can execute any type of instructions associated with the data to achieve the operations detailed herein. Any processor disclosed herein could transform an element or an article (for example, data) from one state or thing to another state or thing. In another example, some activities outlined herein may be implemented with fixed logic or programmable logic (for example, software and/or computer instructions executed by a processor) and the elements identified herein could be some type of a programmable processor, programmable digital logic (for example, an FPGA, an erasable programmable read only memory (EPROM), an electrically erasable programmable read only memory (EEPROM)), an ASIC that includes digital logic, software, code, electronic instructions, flash memory, optical disks, CD-ROMs, DVD ROMs, magnetic or optical cards, other types of machine-readable mediums suitable for storing electronic instructions, or any suitable combination thereof.

In operation, processors may store information in any suitable type of non-transitory storage medium (for example, random access memory (RAM), read only memory (ROM), FPGA, EPROM, electrically erasable programmable ROM (EEPROM), etc.), software, hardware, or in any other suitable component, device, element, or object where appropriate and based on particular needs. Further, the information being tracked, sent, received, or stored in a processor could be provided in any database, register, table, cache, queue, control list, or storage structure, based on particular needs and implementations, all of which could be referenced in any suitable timeframe.

Any of the memory items discussed herein should be construed as being encompassed within the broad term ‘memory.’ Similarly, any of the potential processing elements, modules, and machines described herein should be construed as being encompassed within the broad term ‘microprocessor’ or ‘processor.’ Furthermore, in various examples, the processors, memories, network cards, buses, storage devices, related peripherals, and other hardware elements described herein may be realized by a processor, memory, and other related devices configured by software or firmware to emulate or virtualize the functions of those hardware elements.

Further, it should be appreciated that a computer may be embodied in any of a number of forms, such as a rack-mounted computer, a desktop computer, a laptop computer, or a tablet computer, as non-limiting examples. Additionally, a computer may be embedded in a device not generally regarded as a computer but with suitable processing capabilities, including a personal digital assistant (PDA), a smart phone, a mobile phone, an iPad, or any other suitable portable or fixed electronic device.

Also, a computer may have one or more input and output devices. These devices can be used, among other things, to present a user interface. Examples of output devices that may be used to provide a user interface include printers or display screens for visual presentation of output and speakers or other sound generating devices for audible presentation of output. Examples of input devices that may be used for a user interface include keyboards, and pointing devices, such as mice, touch pads, and digitizing tablets. As another example, a computer may receive input information through speech recognition or in other audible formats.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks or wired networks.

Computer-executable instructions may be in many forms, such as program modules, executed by one or more computers or other devices. Generally, program modules include routines, programs, objects, components, data structures, etc. that performs particular tasks or implement particular abstract data types. Typically, the functionality of the program modules may be combined or distributed as desired in various examples.

The terms “program” or “software” are used herein in a generic sense to refer to any type of computer code or set of computer-executable instructions that may be employed to program a computer or other processor to implement various aspects as described above. Additionally, it should be appreciated that according to one aspect, one or more computer programs that when executed perform methods of the present application need not reside on a single computer or processor, but may be distributed in a modular fashion among a number of different computers or processors to implement various aspects of the present application.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

When implemented in software, the software code may be executed on any suitable processor or collection of processors, whether provided in a single computer or distributed among multiple computers.

Computer program logic implementing all or part of the functionality described herein is embodied in various forms, including, but in no way limited to, a source code form, a computer executable form, a hardware description form, a computer-implemented method with memory storing code/instructions therein, and various intermediate forms (for example, mask works, or forms generated by an assembler, compiler, linker, or locator). In an example, source code includes a series of computer program instructions implemented in various programming languages, such as an object code, an assembly language, or a high-level language such as OpenCL, RTL, Verilog, VHDL, Fortran, C, C++, JAVA, or HTML for use with various operating systems or operating environments. The source code may define and use various data structures and communication messages. The source code may be in a computer executable form (e.g., via an interpreter), or the source code may be converted (e.g., via a translator, assembler, or compiler) into a computer executable form.

In some examples, any number of electrical circuits of the FIGURES may be implemented on a board of an associated electronic device. The board can be a general circuit board that can hold various components of the internal electronic system of the electronic device and, further, provide connectors for other peripherals. More specifically, the board can provide the electrical connections by which the other components of the system can communicate electrically. Any suitable processors (inclusive of digital signal processors, microprocessors, supporting chipsets, etc.), memory elements, etc. can be suitably coupled to the board based on particular configuration needs, processing demands, computer designs, etc.

Other components such as external storage, additional sensors, controllers for audio/video display, and peripheral devices may be attached to the board as plug-in cards, via cables, or integrated into the board itself. In another example, the electrical circuits of the FIGURES may be implemented as standalone modules (e.g., a device with associated components and circuitry configured to perform a specific application or function) or implemented as plug-in modules into application-specific hardware of electronic devices.

Note that with the numerous examples provided herein, interaction may be described in terms of two, three, four, or more electrical components. However, this has been done for purposes of clarity and example only. It should be appreciated that the system can be consolidated in any suitable manner. Along similar design alternatives, any of the illustrated components, modules, and elements of the FIGURES may be combined in various possible configurations, all of which are clearly within the broad scope of this disclosure.

In certain cases, it may be easier to describe one or more of the functionalities of a given set of flows by only referencing a limited number of electrical elements. It should be appreciated that the electrical circuits of the FIGURES and its teachings are readily scalable and can accommodate a large number of components, as well as more complicated/sophisticated arrangements and configurations. Accordingly, the examples provided should not limit the scope or inhibit the broad teachings of the electrical circuits as potentially applied to a myriad of other architectures.

Also, as described, some aspects may be embodied as one or more methods. The acts performed as part of the method may be ordered in any suitable way. Accordingly, examples may be constructed in which acts are performed in an order different than illustrated, which may include performing some acts simultaneously, even though shown as sequential acts in illustrative examples.

### Interpretation of Terms

All definitions, as defined and used herein, should be understood to control over dictionary definitions, definitions in documents incorporated by reference, and/or ordinary meanings of the defined terms. Unless the context clearly requires otherwise, throughout the description and the claims: “comprise,” “comprising,” and the like are to be construed in an inclusive sense, as opposed to an exclusive or exhaustive sense; that is to say, in the sense of “including, but not limited to.” “Connected,” “coupled,” or any variant thereof, means any connection or coupling, either direct or indirect, between two or more elements. The coupling or connection between the elements can be physical, logical, or a combination thereof. “Herein,” “above,” “below,” and words of similar import, when used to describe this specification shall refer to this specification as a whole and not to any particular portions of this specification. “Or,” in reference to a list of two or more items, covers all of the following interpretations of the word: any of the items in the list, all of the items in the list, and any combination of the items in the list. The singular forms “a,” “an” and “the” also include the meaning of any appropriate plural forms.

Words that indicate directions such as “vertical”, “transverse”, “horizontal”, “upward”, “downward”, “forward”, “backward”, “inward”, “outward”, “vertical”, “transverse”, “left”, “right”, “front”, “back”, “top”, “bottom”, “below”, “above”, “under”, and the like, used in this description and any accompanying claims (where present) depend on the specific orientation of the apparatus described and illustrated. The subject matter described herein may assume various alternative orientations. Accordingly, these directional terms are not strictly defined and should not be interpreted narrowly.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined.

Elements other than those specifically identified by the “and/or” clause may optionally be present, whether related or unrelated to those elements specifically identified. Thus, as a non-limiting example, a reference to “A and/or B”, when used in conjunction with open-ended language such as “comprising” may refer, in one example, to A only (optionally including elements other than B); in another example, to B only (optionally including elements other than A); in yet another example, to both A and B (optionally including other elements); etc.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

Thus, as a non-limiting example, “at least one of A and B” (or, equivalently, “at least one of A or B,” or, equivalently “at least one of A and/or B”) may refer, in one example, to at least one, optionally including more than one, A, with no B present (and optionally including elements other than B); in another example, to at least one, optionally including more than one, B, with no A present (and optionally including elements other than A); in yet another example, to at least one, optionally including more than one, A, and at least one, optionally including more than one, B (and optionally including other elements); etc.

As used herein, the term “between” is to be inclusive unless indicated otherwise. For example, “between A and B” includes A and B unless indicated otherwise.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

Numerous other changes, substitutions, variations, alterations, and modifications may be ascertained to one skilled in the art and it is intended that the present disclosure encompass all such changes, substitutions, variations, alterations, and modifications as falling within the scope of the appended claims.

In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke 35 U.S.C. § 112(f) as it exists on the date of the filing hereof unless the words “means for” or “steps for” are specifically used in the particular claims; and (b) does not intend, by any statement in the disclosure, to limit this disclosure in any way that is not otherwise reflected in the appended claims.

The present invention should therefore not be considered limited to the particular examples described above. Various modifications, equivalent processes, as well as numerous structures to which the present invention may be applicable, will be readily apparent to those skilled in the art to which the present invention is directed upon review of the present disclosure.

It should be understood that the detailed description and specific examples, while indicating examples of the systems and methods are intended for purposes of illustration only and are not intended to limit the scope. These and other features, aspects, and advantages of the systems and methods of the present invention can be better understood from the description, appended claims or aspects, and accompanying drawings. It should be understood that the Figures are merely illustrative and are not drawn to scale. It should also be understood that the same reference numerals are used throughout the figures to indicate the same or similar parts.

Other variations to the disclosed examples can be understood and effected by those skilled in the art in practicing the disclosure, from a study of the drawings, the disclosure, and the appended aspects or claims. In the aspects or claims, the word “comprising” does not exclude other elements or steps, and the indefinite article “a” or “an” does not exclude a plurality. The mere fact that certain measures are recited in mutually different dependent aspects or claims does not indicate that a combination of these measures cannot be used to advantage. Any reference signs in the claims should not be construed as limited the scope.

What is claimed is:

1. A method for battery operation, the method comprising:
obtaining, by a computer system for each of at least one baseline cell in a baseline battery of a battery type over at least one frequency, [1] at least one component of a complex impedance based on electrochemical impedance spectroscopy (EIS), thereby obtaining a baseline complex impedance for each baseline cell and [2] one or more limits on deviation from the baseline complex impedance;
first measuring, by a computer system using EIS over the at least one frequency, on one or more cells of a measurement battery of the battery type, each measurement battery cell corresponding to a baseline cell, the at least one component of a complex impedance, thereby obtaining a first measured complex impedance;
first determining, by the computer system for each measured cell, that a difference between the first measured complex impedance and the baseline complex impedance falls outside at least one of the one or more limits;
first identifying, by the computer system, an anomaly based on the determined difference falling outside at least one of the one or more limits; and
performing, by the computer system and in response to the determining, one or more of:
notifying one or more of an end user of a system comprising the measurement battery and a non-end user entity associated with the measurement battery of the identified anomaly;
disconnecting each cell associated with the identified anomaly;
deploying safety measures associated with the identified anomaly; and
recording the identified anomaly.

2. The method of claim 1, wherein the baseline battery is the measurement battery and the baseline complex impedance is obtained prior to the measured complex impedance.

3. The method of claim 1, wherein obtaining comprises one or more of: obtaining as data; obtaining through simulation; and obtaining through measurement.

4. The method of claim 1, wherein the at least one frequency comprises one or more of: a sweep across a range, and at least one discrete frequency.

5. The method of claim 1, wherein first measuring comprises adjusting at least one of the baseline complex impedance and the first measured complex impedance for parasitics.

6. The method of claim 1:
wherein:
obtaining occurs under baseline conditions and first measuring occurs under measurement conditions; and
baseline conditions and measurement conditions comprise one or more of: cell state of charge (SoC), cell temperature, cell position in a battery, and mode of a system including the battery.

7. The method of claim 6, first determining comprises compensating at least one of [1] the baseline complex impedance and [2] the first measured complex impedance for at least one difference between the measurement conditions and the baseline conditions.

8. The method of claim 1, wherein limits are based at least in part on position of a cell in a battery.

9. The method of claim 1, wherein obtaining limits comprises establishing limits through historical limits on cells, batteries comprising the cells, and systems comprising the batteries.

10. The method of claim 1, wherein first identifying an anomaly based on the determined difference comprises on or more of:
identifying a translation along a real impedance Re(Z) axis between the first measured complex impedance and the baseline complex impedance over time as a cell weld defect in a multicell battery;
identifying a decrease in a low frequency response between the first measured complex impedance and the baseline complex impedance over time as a change in properties of electrolytes of a cell; and
identifying loss of area under an EIS Nyquist plot curve for Im(Z) less than or equal to “0” between the first measured complex impedance and the baseline complex impedance over time as a reduction in an ampere-hour capacity of the cell.

11. The method of claim 1, wherein:
obtaining occurs under baseline conditions and first measuring occurs under measurement conditions; and the baseline conditions and the measurement conditions include adjacency of each cell in a multicell battery, and at least one obtained limit is applicable to candidate thermal events in a cell and at least one obtained limit is applicable to candidate thermal events adjacent to a cell;
first determining comprises second determining a difference outside the limit applicable to candidate thermal events for a given cell; and
the method further comprises:
second identifying one or more cells adjacent to the given cell; and
third determining, for at least one of the one or more cells identified as adjacent to the given cell, a difference outside the limit applicable to candidate thermal event adjacent cells;
wherein first identifying comprises identifying a thermal event for a given cell based on the second determining and the third determining.

12. A method for battery operation, the method comprising:
for a baseline battery and a measurement battery each configured as a same iSjP battery type, where iS indicates i cell groups in series (S), each cell group i comprising j cells in parallel (P) and the baseline cell is a baseline cell group of j cells in parallel:
obtaining, by one or more computer systems, a real component of complex impedance Re(Z) of a baseline cell group of a baseline cell group type at one or more frequencies for each permutation of zero or one cell of the cell group disconnected, thereby obtaining disconnected parallel cell baseline complex impedances for the baseline battery cell group;
measuring, by the one or more computer systems and using EIS over the one or more frequencies, on a measurement battery cell group of the cell group type, the real component of complex impedance Re(Z), thereby obtaining a first measured complex impedance; and
identifying, by the one or more computer systems, as “disconnected” a cell corresponding to the disconnected parallel cell baseline complex impedance correlating best to the measured complex impedance.

13. A system for battery operation, comprising:
a memory storing instructions therein; and
one or more processors communicatively coupled with the memory, the one or more processors being configured to execute the instructions to:
obtain, for each of at least one baseline cell in a baseline battery of a battery type over at least one frequency, [1] at least one component of a complex impedance based on electrochemical impedance spectroscopy (EIS), thereby obtaining a baseline complex impedance for each baseline cell and [2] one or more limits on deviation from the baseline complex impedance;
first measure, using EIS over the at least one frequency, on one or more cells of a measurement battery of the battery type, each measurement battery cell corresponding to a baseline cell, the at least one component of a complex impedance, thereby obtaining a first measured complex impedance;
first determine, for each measured cell, that a difference between the first measured complex impedance and the baseline complex impedance falls outside at least one of the one or more limits;
first identify an anomaly based on the determined difference falling outside at least one of the one or more limits; and
perform, in response to the determining, one or more of:
notifying one or more of an end user of a system comprising the measurement battery and a non-end user entity associated with the measurement battery of the identified anomaly;
disconnecting each cell associated with the identified anomaly;
deploying safety measures associated with the identified anomaly; and
recording the identified anomaly.

14. The system of claim 13, wherein the baseline battery is the measurement battery and the baseline complex impedance is obtained prior to the measured complex impedance.

15. The system of claim 13, wherein obtaining comprises one or more of: obtaining as data; obtaining through simulation; and obtaining through measurement.

16. The system of claim 13, wherein the at least one frequency comprises one or more of: a sweep across a range, and at least one discrete frequency.

17. The system of claim 13, wherein first measuring comprises adjusting at least one of the baseline complex impedance and the first measured complex impedance for parasitics.

18. The system of claim 13:
wherein:
obtaining occurs under baseline conditions and first measuring occurs under measurement conditions; and
baseline conditions and measurement conditions comprise one or more of: cell state of charge (SoC), cell temperature, cell position in a battery, and mode of a system including the battery.

19. The system of claim 18, first determining comprises compensating at least one of [1] the baseline complex impedance and [2] the first measured complex impedance for at least one difference between the measurement conditions and the baseline conditions.

20. The system of claim 13, wherein limits are based at least in part on position of a cell in a battery.

21. The system of claim 13, wherein obtaining limits comprises establishing limits through historical limits on cells, batteries comprising the cells, and systems comprising the batteries.

22. The system of claim 13, wherein first identifying an anomaly based on the determined difference comprises on or more of:
identifying a translation along a real impedance Re(Z) axis between the first measured complex impedance and the baseline complex impedance over time as a cell weld defect in a multicell battery;
identifying a decrease in a low frequency response between the first measured complex impedance and the baseline complex impedance over time as a change in properties of electrolytes of a cell; and
identifying loss of area under a EIS Nyquist plot curve for Im(Z) less than or equal to “0” between the first measured complex impedance and the baseline complex impedance over time as a reduction in an ampere-hour capacity of the cell.

23. The system of claim 13, wherein:
obtaining occurs under baseline conditions and first measuring occurs under measurement conditions; and the baseline conditions and the measurement conditions include adjacency of each cell in a multicell battery, and at least one obtained limit is applicable to candidate thermal events in a cell and at least one obtained limit is applicable to candidate thermal events adjacent to a cell;
first determining comprises second determining a difference outside the limit applicable to candidate thermal events for a given cell; and
the one or more processors are further configured to execute the instructions to:
second identify one or more cells adjacent to the given cell;
third determine, for at least one of the one or more cells identified as adjacent to the given cell, a difference outside the limit applicable to candidate thermal event adjacent cells; and
wherein first identifying comprises identifying a thermal event for a given cell based on the second determining and the third determining.

24. A system for battery operation, comprising:
a memory storing instructions therein; and
one or more processors communicatively coupled with the memory, the one or more processors being configured to execute the instructions to:
for a baseline battery and a measurement battery each configured as a same iSjP battery type, where iS indicates i cell groups in series (S), each cell group i comprising j cells in parallel (P) and the baseline cell is a baseline cell group of j cells in parallel:
obtain a real component of complex impedance Re(Z) of a baseline cell group of a baseline cell group type at one or more frequencies for each permutation of zero or one cell of the cell group disconnected, thereby obtaining disconnected parallel cell baseline complex impedances for the baseline battery cell group;
measure, using EIS over the one or more frequencies, on a measurement battery cell group of the cell group type, the real component of complex impedance Re(Z), thereby obtaining a first measured complex impedance; and
identify as “disconnected” a cell corresponding to the disconnected parallel cell baseline complex impedance correlating best to the measured complex impedance.

25. A non-transitory computer-readable medium storing computer executable instructions, the instructions when executed by one of more processors operative to:
obtain, for each of at least one baseline cell in a baseline battery of a battery type over at least one frequency, [1] at least one component of a complex impedance based on electrochemical impedance spectroscopy (EIS), thereby obtaining a baseline complex impedance for each baseline cell and [2] one or more limits on deviation from the baseline complex impedance;
first measure, using EIS over the at least one frequency, on one or more cells of a measurement battery of the battery type, each measurement battery cell corresponding to a baseline cell, the at least one component of a complex impedance, thereby obtaining a first measured complex impedance;
first determine, for each measured cell, that a difference between the first measured complex impedance and the baseline complex impedance falls outside at least one of the one or more limits;
first identify an anomaly based on the determined difference falling outside at least one of the one or more limits; and
perform, in response to the determining, one or more of:
notifying one or more of an end user of a system comprising the measurement battery and a non-end user entity associated with the measurement battery of the identified anomaly;
disconnecting each cell associated with the identified anomaly;
deploying safety measures associated with the identified anomaly; and
recording the identified anomaly.

26. A non-transitory computer-readable medium storing computer executable instructions, the instructions when executed by one of more processors operative to:
for a baseline battery and a measurement battery each configured as a same iSjP battery type, where iS indicates i cell groups in series (S), each cell group i comprising j cells in parallel (P) and the baseline cell is a baseline cell group of j cells in parallel:
obtain a real component of complex impedance Re(Z) of a baseline cell group of a baseline cell group type at one or more frequencies for each permutation of zero or one cell of the cell group disconnected, thereby obtaining disconnected parallel cell baseline complex impedances for the baseline battery cell group;
measure, using EIS over the one or more frequencies, on a measurement battery cell group of the cell group type, the real component of complex impedance Re(Z), thereby obtaining a first measured complex impedance; and
identify as “disconnected” a cell corresponding to the disconnected parallel cell baseline complex impedance correlating best to the measured complex impedance.
